(19) United States
(12) Patent Application Publication
(10) Pub. No.: US 2026/0004160 A1
(43) Pub. Date: Jan. 1, 2026

(54) MULTI-MODAL DESIGN INFORMATION UNIFIED EXPRESSION AND REASONING METHOD BASED ON LARGE MODEL

(71) Applicant: ZHEJIANG UNIVERSITY, HANGZHOU, Zhejiang Province (CN)

(72) Inventors: PEI CHEN, HANGZHOU, ZHEJIANG PROVINCE (CN); WENZHENG SONG, HANGZHOU, ZHEJIANG PROVINCE (CN); ZHUOYI CHENG, HANGZHOU, ZHEJIANG PROVINCE (CN); LINGYUN SUN, HANGZHOU, ZHEJIANG PROVINCE (CN)

(21) Appl. No.: 19/120,664

(22) PCT Filed: Nov. 26, 2024
(86) PCT No.: PCT/CN2024/134528

§ 371 Date: Apr. 11, 2025

(30) Foreign Application Priority Data
Jun. 7, 2024 (CN) 202410734774.0

(51) Int. Cl. G06N 5/022; G06F 30/20

(52) U.S. Cl. CPC G06N 5/022; G06F 30/20

(57) ABSTRACT

The present invention discloses a multi-modal design information unified expression and reasoning method based on a large language model. The present invention utilizes the large language model to extract corresponding information of function-behavior-structure from a design scheme, so as to construct a graph network of the function-behavior-structure, thereby achieving a relatively accurate unified expression of multi-modal design information. The present invention obtains differences in three dimensions of the function-behavior-structure based on comparison of graph networks at different moments. Through the difference in each dimension, the large language model is used to obtain an optimized scheme corresponding to the dimension to reason out a design idea and a design process of a designer in each dimension through the large language model, and the design scheme in each dimension is optimized based on the design idea and the design process, and then, the optimized schemes corresponding to the three dimensions are aggregated to obtain the optimized design scheme.

### TECHNICAL FIELD

The present invention belongs to the field of computer-aided design, and specifically relates to a multi-modal design information unified expression and reasoning method based on a large language model.

### BACKGROUND TECHNOLOGY

A product concept design is a complex process of generating a product scheme according to a design task. It requires a designer to conduct in-depth analysis, understanding, and reasoning of information contained in the design scheme, so as to capture key information in abstract and ambiguous user requirements and reason out a feasible and high-quality design scheme. Most of traditional computer-aided concept design reasoning methods (such as case-based reasoning, qualitative reasoning, and reasoning using a neural network) are mostly imitations and followings of existing information such as a design case and a design rule, and they fail to truly understand an evolution process of the schemes. These reasoning methods have high requirements for correlation between auxiliary information and design tasks. Therefore, they are usually only applicable to specific products and lack general design knowledge and generalization ability.

A brain-inspired cognitive model for a product conceptual innovative design mainly processes design information presented in a multi-modal way, and forms a semantic cognitive space to understand, express, and deduce the design information, so as to realize knowledge-based transformation of the design information. Existing mainstream computer-aided design or computer-aided concept design technologies focus on a single medium, such as a natural language, a symbolic logic, a two-dimensional sketch, a two-dimensional drawing, and a three-dimensional model. However, a human designer processes the design information and advances the design process in a multi-modal and cross-media way. In a traditional computer-aided design mode, there are significant differences in the way of processing the design information between the human designer and an intelligent system, making it difficult to integrate them. A brain-inspired cognitive model for a conceptual innovative design has two new characteristics: one is to endow a computer or an intelligent system with an ability to express and process multi-modal design information, and the other is to provide a basis for processing of the design information through human-machine collaboration. The multi-modal design information is manifested as text, an image, a digital model, and a neural network. Representation and processing of multi-modal information are fundamental characteristics of brain-like cognition. The processing of design information through the human-machine collaboration utilizes an intelligent algorithm inspired by the brain-like cognition to enhance abilities of intelligent systems and human designers in problem definition, design solution finding, inspiration generation, and other aspects.

During a human-machine collaborative design process, a Large Language Model (LLM) is gradually becoming a powerful assistant for designers. Using the LLM for product concept design scheme reasoning can leverage its powerful text understanding ability and massive knowledge reserve, effectively solving problems of requiring auxiliary knowledge and lacking generalization in traditional reasoning methods. In addition, development of multi-modal large language models provides support for understanding, transforming, and generating multi-modal data. The multi-modal large language models can be utilized to integrate the multi-modal design information in the design scheme, enhancing comprehensiveness and accuracy of understanding of the design scheme.

However, the existing multi-modal large language models only focus on modality alignment when processing the multi-modal data, that is, mapping the multi-modal data to a text space that can be understood by the LLM. Merely using the multi-modal large language models to understand design schemes lack sufficient exploration of semantic relationships among the multi-modal design information. Therefore, there is still a lack of a product concept design scheme reasoning method that can deeply understand both the multi-modal information of the design scheme and its evolution process. In other words, in the existing concept design reasoning methods involving large language models, feedback provided by the large language models mostly responds to questions or instructions of designers, failing to fully understand and utilize design information in a complete design scheme, and thus failing to provide timely and accurate feedback on design ideas of the designers and the current design progress.

### SUMMARY OF THE INVENTION

The present invention provides a multi-modal design information unified expression and reasoning method based on a large language model. This method can transform important information in a design scheme, namely, functional, structural, and behavioral information and their relationships, into a graph network, thereby achieving a relatively accurate multi-modal unified expression. Based on the changes in the graph networks at different moments under the multi-modal unified expression, the large language model can accurately and promptly understand an idea of a designer and a design process, and further optimize the design scheme.

A specific embodiment of the present invention provides a multi-modal design information unified expression and reasoning method based on a large language model, comprising the following steps:
extracting new structural nodes and connections between the new structural nodes and other structural nodes from a current design scheme by using the large language model based on a graph network at a previous moment, and updating the graph network at the previous moment to obtain a first graph network; extracting new functional nodes and connections between the new functional nodes and the new structural nodes and/or other structural nodes from the current design scheme by using the large language model based on the first graph network, and updating the first graph network to obtain a second graph network; and extracting new behavioral nodes and connections between the new behavioral nodes and the new functional nodes and/or other functional nodes from the current design scheme by using the large language model based on the second graph network, and updating the second graph network to obtain a graph network at a current moment; and
comparing graph networks at different moments through the large language model by using a mind map to obtain change descriptions in three dimensions of function, structure, and behavior; using the large language model to obtain a plurality of design schemes corresponding to each dimension respectively based on the change descriptions in the three dimensions of function, structure, and behavior; using the large language model to evaluate the plurality of design schemes in each dimension respectively based on a set evaluation rule to obtain optimal design schemes corresponding to the function, structure, and behavior; and aggregating the optimal design schemes corresponding to the function, structure, and behavior to obtain an optimized design scheme at the current moment.

Further, the extracting new structural nodes and edges between the new structural nodes and other structural nodes from a current design scheme by using the large language model based on a graph network at a previous moment comprises:
inputting a first prompt word into the large language model to obtain the new structural nodes, wherein the first prompt word is constructed by a first instructional statement, a first output example, the current design scheme, and the graph network at the previous moment; the large language model obtains a first instruction through the first instructional statement; the first instruction is to obtain the new structural nodes; and the large language model makes a statement structure of an output result thereof the same as that of the first output example through the first output example; and
inputting a second prompt word into the large language model to obtain the edges between the new structural nodes and the other structural nodes, wherein the second prompt word is constructed by a second instructional statement, a second output example, a set of structural nodes, the current design scheme, and the graph network at the previous moment; the large language model obtains a second instruction through the second instructional statement; the second instruction is to obtain the edges between the new structural nodes and the other structural nodes; the large language model makes the statement structure of the output result thereof the same as that of the second output example through the second output example; the set of structural nodes comprises the new structural nodes and the other structural nodes; and the other structural nodes are structural nodes contained in the graph network at the previous moment.

Further, the extracting new functional nodes and edges between the new functional nodes and the new structural nodes and/or other structural nodes from the current design scheme by using the large language model based on the first graph network comprises:
inputting a third prompt word into the large language model to obtain the new functional nodes, wherein the third prompt word is constructed by a third instructional statement, a third output example, the current design scheme, the graph network at the previous moment and a set of structural nodes; the large language model obtains a third instruction through the third instructional statement; the third instruction is to obtain the new structural nodes; and the large language model makes a statement structure of an output result thereof the same as that of the third output example through the third output example; the set of structural nodes comprises the new structural nodes and the other structural nodes; and the other structural nodes are structural nodes contained in the graph network at the previous moment; and
inputting a fourth prompt word into the large language model to obtain the edges between the new functional nodes and the new structural nodes and/or the other structural nodes, wherein the fourth prompt word is constructed by a fourth instructional statement, a fourth output example, the current design scheme, the graph network at the previous moment and the set of structural nodes; the large language model obtains a fourth instruction through the fourth instructional statement; the fourth instruction is to obtain the edges between the new functional nodes and the new structural nodes and/or the other structural nodes; and the large language model makes the statement structure of the output result thereof the same as that of the fourth output example through the fourth output example.

Further, the extracting new behavioral nodes and edges between the new behavioral nodes and the new functional nodes and/or other functional nodes from the current design scheme by using the large language model based on the second graph network comprises:
inputting a fifth prompt word into the large language model to obtain the new behavioral nodes, wherein the fifth prompt word is constructed by a fifth instructional statement, a fifth output example, the current design scheme, the graph network at the previous moment, a set of structural nodes, and a set of functional nodes; the large language model obtains a fifth instruction through the fifth instructional statement; the fifth instruction is to obtain the new behavioral nodes; the large language model makes a statement structure of an output result thereof the same as that of the fifth output example through the fifth output example; the set of structural nodes comprises the new structural nodes and the other structural nodes; the other structural nodes are structural nodes contained in the graph network at the previous moment; the set of functional nodes comprises the new functional nodes and the other functional nodes; the other functional nodes are functional nodes contained in the graph network at the previous moment; and
inputting a sixth prompt word into the large language model to obtain the edges between the new behavioral nodes and the new functional nodes and/or the other functional nodes, wherein the sixth prompt word is constructed by a sixth instructional statement, a sixth output example, the current design scheme, the graph network at the previous moment, the set of structural nodes, and the set of functional nodes; the large language model obtains a sixth instruction through the sixth instructional statement; the sixth instruction is to obtain the edges between the new behavioral nodes and the new functional nodes and/or the other functional nodes; and the large language model makes the statement structure of the output result thereof the same as that of the sixth output example through the sixth output example.

Further, the method for constructing the first graph network comprises:
S1: using the large language model to extract a target product from an initial design scheme, and taking the target product as a first structural node;
S2: using the large language model to extract structural nodes related to the first structural node and edges between the first structural node and related structural nodes thereof from the current design scheme based on the extracted first structural node, so as to obtain a structural node graph network;
S3: using the large language model to extract corresponding functional nodes and edges between the functional nodes and the structural nodes of the structural node graph network from the current design scheme based on the structural node graph network, and updating the structural node graph network based on the corresponding functional nodes and the edges between the functional nodes and the structural nodes of the structural node graph network to obtain a graph network containing the structural nodes and the functional nodes; and
S4: using the large language model to extract corresponding behavioral nodes and edges between the behavioral nodes and the functional nodes obtained in step S2 from the current design scheme based on the graph network containing the structural nodes and the functional nodes, and updating the graph network based on the corresponding behavioral nodes and the edges between the behavioral nodes and the functional nodes obtained in step S2 to obtain the first graph network.

Further, the comparing graph networks at the previous moment and the current moment through the large language model by using a mind map to obtain change descriptions in three dimensions of function, structure, and behavior comprises:
decomposing the graph networks at the previous moment and the current moment into the three dimensions of function, behavior, and structure respectively through the mind map, and using the large language model to compare differences of each dimension at different moments so as to obtain the change descriptions in the three dimensions of function, structure, and behavior.

Further, the mind map comprises a controller, a prompt word generator, a parser, and an evaluation module,
wherein the controller is configured to construct a reasoning state graph and an operation graph based on graph network data at different moments, wherein the reasoning state graph comprises a plurality of thought nodes and edges among the thought nodes, the thought nodes comprise four-level thought nodes, thought nodes of a first level are the change descriptions in the three dimensions of function, structure, and behavior, thought nodes of a second level are a plurality of design schemes corresponding to each dimension, thought nodes of a third level are optimal design schemes corresponding to each dimension, thought nodes of a fourth level are an optimized design scheme at the current moment, the edges among the thought nodes are used to represent connection relationships among the thought nodes at different levels, and the operation graph is an operation process constructed by a plurality of operation instructions from the thought nodes of the first level to the thought nodes of the fourth level based on the reasoning state graph;
the prompt word generator is configured to generate corresponding prompt words based on each operation instruction, and input the prompt words into the large language model to generate descriptive information;
the parser is configured to extract key information from the descriptive information and structure the key information into targeted thought nodes; and
the evaluation module is configured to evaluate the plurality of design schemes in each dimension respectively through the large language model based on the set evaluation rule to obtain the optimal schemes corresponding to the three dimensions of function, structure, and behavior.

Further, the operation instructions are used to make thought nodes at a current level point to the thought nodes at a next level, and the operation instructions comprise generation, aggregation, refinement, scoring, and selection.

Further, before inputting the graph network into the large language model, the graph network is stored in a form of an adjacency list, and the stored graph network is converted into a natural language description in a form of a string.

Compared with the prior art, the beneficial effects of the present invention are as follows:

The present invention utilizes the large language model to extract corresponding information of function-behavior-structure from a design scheme, so as to construct a graph network of the function-behavior-structure, thereby achieving a relatively accurate unified expression of multi-modal design information.

The present invention obtains differences in three dimensions of the function-behavior-structure based on comparison of graph networks of each dimension at different moments. Through the difference in each dimension, the large language model is used to obtain an optimized scheme corresponding to the dimension to reason out a design idea and a design process of a designer in each dimension through the large language model, and the design scheme in each dimension is optimized based on the design idea and the design process, and then the optimized schemes corresponding to the three dimensions are aggregated to obtain the optimized design scheme.

### BRIEF DESCRIPTION OF THE DRAWINGS

FIG. 1 is a flowchart of a multi-modal design information unified expression and reasoning method based on a large language model provided by a specific embodiment of the present invention;

FIG. 2 is a flowchart of converting a current design scheme into a graph network at a current moment provided by a specific embodiment of the present invention; and

FIG. 3 is a flowchart of obtaining an optimized design scheme provided by a specific embodiment of the present invention.

### DETAILED DESCRIPTION OF THE EMBODIMENTS

The present invention is described in detail below in conjunction with specific embodiments. The following embodiments help those skilled in the art to further understand the present invention, but do not limit the present invention in any form. It should be noted that for those of ordinary skill in the art, without departing from the concept of the present invention, several changes and improvements can also be made. All these fall within the protection scope of the present invention.

In view of the fact that, in the prior art, large language models can neither accurately achieve a unified expression of multi-modal design information, nor can they reasonably optimize a design scheme in a timely and accurate manner based on a design intention and progress. The specific embodiments of the present invention utilize a graph network to accurately and structurally express function-behavior-structure (FBS) information in a multi-modal design scheme. By comparing graph networks at different moments, the large language model can accurately understand the design intention and progress, and then reasonably optimize the current design scheme. Specific descriptions of a multi-modal design information unified expression and reasoning method based on a large language model provided by specific embodiments of the present invention are as follows.

A generation process of the large language model provided by the specific embodiments of the present invention can be uniformly expressed as R=φₙ(p_{θ}(Y|promptₙ)), wherein p_{θ} represents a pre-trained large language model, θ represents a parameter of the large language model; promptₙ represents a prompt word designed for a different task n, that is, an input of the large language model; Y represents an output of the large language model; φₙ is a parsing function of the task n, which processes an output content into storable data R.

Based on definitions of three design concepts of function, behavior, and structure in a “function-behavior-structure” (FBS) model, the specific embodiments of the present invention utilize the LLM to extract corresponding information from the multi-modal design scheme and construct a “function-behavior-structure” graph, thereby achieving a structured representation of the multi-modal design information. By converting a graph network constructed at a previous moment into a natural language description and adding it to the prompt words, the LLM is guided to update nodes and edges on this basis to obtain a graph network at a current moment. Thus, a discrete dynamic graph is constructed through the graph networks at a plurality of moments, realizing modeling of a deduction process of the multi-modal concept design scheme.

In a specific embodiment, to realize a structured representation of a lengthy and complex multi-modal design scheme through a graph network, it is first necessary to extract key design concepts from it and classify them appropriately to make relationships among the design concepts more logical. This embodiment uses the “function-behavior-structure” (FBS) model widely used in a product design field to extract three types of key design concepts, namely the function, behavior, and structure, from the multi-modal design scheme.

The structure provided by the specific embodiments of the present invention comprises a target product and its component elements, which are usually actual physical entities, representing what a design object is. The function provided by the specific embodiments of the present invention is a description of design intentions of the target product itself and its components in the design scheme, which is closely related to user requirements and explains why a certain design object is introduced. The behavior provided by the specific embodiments of the present invention refers to some attributes brought or expected to be brought by the structure, that is, what the design object can do.

The specific embodiments of the present invention record the graph networks at a series of moments through a graph sequence constructed by discrete graph networks, and use the discrete dynamic graphs to model the evolution process of the design scheme. After a designer chooses to save a design scheme Xₜ at a current moment t, based on a function-behavior-structure graph Gₜ₋₁ of a previous time node t−1, a new design concept such as the function, behavior, and structure and relationships among them are extracted from Xₜ and added to Gₜ₋₁ as nodes and edges respectively to obtain a new graph network Gₜ. In this way, a discrete dynamic graph {G₀, G₁, . . . , Gₜ} is obtained to realize modeling of a deduction process of the multi-modal concept design scheme, wherein G₀=∅.

Specifically, corresponding prompt words are designed to guide the multi-modal large language model to extract new added design concepts such as the function, behavior, and structure from the design scheme Xₜ at the current moment t. A prompt word promptₙ needs to contain an instructional statement instructionₙ, the design scheme Xₜ at the current moment, and the graph network Gₜ₋₁ at the previous moment. An example of such an instructional statement is as follows: “based on the graph network at the previous moment, extracting new component elements from the design scheme at the current moment as structural nodes, this instructional statement only provides keywords which are separated by commas without specific elaboration.” In addition, during each extraction, an output example example related to a task needs to be constructed in promptₙ for an LLM to conduct context-based learning, making an output of the LLM more structured. For example, the example may be “an electric scooter, a scooter handlebar, a scooter body”. Therefore, promptₙ=<instructionₙ, Xₜ, Gₜ₋₁, example, ε>, wherein ε represents additional information added for a specific task.

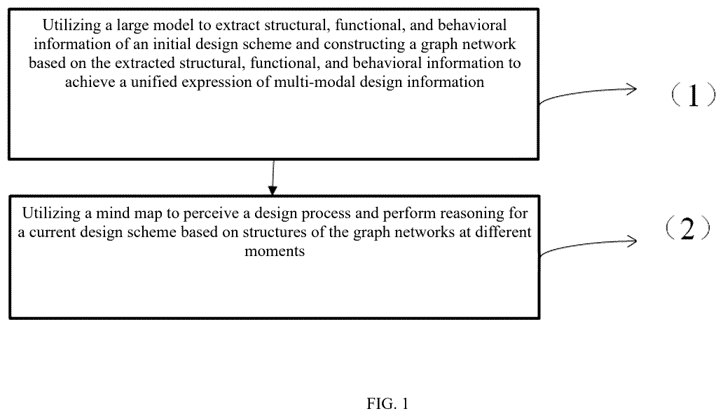

The method for constructing the function-behavior-structure graph network at a certain moment provided by the specific embodiments of the present invention utilizes a multi-modal large language model p_{θ} to extract the design concepts such as the function, behavior, and structure from the multi-modal design scheme Xₜ to form a node set of the graph V=F∪B∪ S, wherein t represents the moment, and F, B, S represent function nodes, behavior nodes and structure nodes respectively. The nodes are connected according to semantic relationships among the design concepts to construct an edge set E⊆V×V, thus the “function-behavior-structure” graph G=(V, E). As shown in FIG. 1, specific steps are as follows:

(1) utilizing the large language model to extract the structural, functional, and behavioral information of the current design scheme and constructing the graph network based on the extracted structural, functional, and behavioral information to achieve the unified expression of the multi-modal design information. The method for constructing the first graph network provided by the specific embodiments of the present invention comprises:

S1: firstly, utilizing the LLM to identify a target product of the design from multi-modal design information of an initial design scheme X₁, taking the target product as a first structural node s₀=φ_{obj}(p_{θ}(Y|prompt_{obj})) in a set of structural nodes which is used as a center of the graph. Then, the set of structural nodes is initialized as S={s₀}, wherein a corresponding prompt word is prompt_{obj}=<instruction_{obj}, X₁, G₀, example>, and instruction_{obj} is an instructional statement for the task of extracting the target product (object, abbreviated as obj).

S2: utilizing the large language model to extract structural nodes ΔS={sᵢ, sᵢ₊₁, . . . sᵢ₊ₖ}=φ_{struct}(p_{θ}(Y|prompt_{struct})) related to the first structural node from the current design scheme Xₜ based on the extracted first structural node, and updating the set of structural nodes S′=S∪ΔS, wherein i represents a sub-script of the first structural node extracted this time, and its value is equal to the number of existing structural nodes; the value of k is the number of structural nodes extracted this time minus one; and a prompt word for the task of extracting the structural concept (structure, abbreviated as struct) provided in this embodiment and used for inputting into the large language model is prompt_{struct}=<instruction_{struct}, Xₜ, Gₜ₋₁, example>. Then, the LLM is utilized to explore possible new relationships among the updated structural nodes, that is, edges ΔE ={(sₘ, sⱼ), . . . }=φ_{edge}(p_{θ}(Y|prompt_{edge})) connecting the first structural node and its related structural nodes, and the set of edges E′=E∪ΔE is updated, wherein (sₘ, sⱼ) represents a directed path sₘ→sⱼ from an m-th node sₘ to a j-th node sⱼ, sₘ, sⱼ∈S′. A prompt word for the task of extracting the structural edge concept (edge) provided in this embodiment and used for inputting into the large language model is prompt_{edge}=<instruction_{edge}, Xₜ, Gₜ₋₁, example, ε>, ε=ΔS. A structural node graph network is obtained through the obtained structural nodes and corresponding edges.

S3: utilizing the LLM to extract related design requirements and target functions from the current design scheme as functional nodes ΔF={fᵤ₀, fᵤ₁, . . . , f_{uw}}=φ_{func}(p_{θ}(Y|prompt_{func})) based on each structural node sᵤ∈S′ in the structural node graph network, wherein u represents a sub-script of the structural node; the value of w is the number of existing structural nodes; the value of w is the number of functional nodes related to the structural node extracted this time minus one; and a prompt word for the task of extracting the functional concept (function, abbreviated as func) provided in this embodiment and used for inputting into the large language model is prompt_{func}=<instruction_{func}, Xₜ, Gₜ₋₁, example, ε>, ε=ΔS. A set of functional nodes F′=F∪ΔF is updated and edges between the functional nodes and the structural nodes in the structural node graph network are updated, and the set of edges E′=E∪ΔE is updated, wherein ΔE={(sᵤ, f_{uw})|f_{uw}∈ΔF}; and the obtained functional nodes and the edges between the functional nodes and the structural nodes are added to the structural node graph network to obtain a bipartite graph network of structural nodes and functional nodes.

S4: utilizing the LLM to extract related attributes b_{ugh} that the structure sᵤ has to achieve a function f_{ug} from the current design scheme as behavioral nodes ΔB={b_{ug0}, b_{ug1}, . . . , b_{ugh}}=φ_{behav}(p_{θ}(Y|prompt_{behav})) based on each “structure-function” pair (sᵤ, f_{ug}), sᵤ∈S′, f_{ug}∈F′ in the bipartite graph network of structural nodes and functional nodes, wherein u represents the sub-script of the structural node; g represents a sub-script of the functional node connected to the structural node sᵤ; the value of h is the number of behavioral nodes related to a functional node f_{ug} and extracted this time minus one; a prompt word for the task of extracting the behavioral concept (behavior, abbreviated as behav) provided in this embodiment and used for inputting into the large language model is prompt_{behav}=<instruction_{behav}, Xₜ, Gₜ₋₁, example, ε>, ε=ΔS+ΔF. A set of behavioral nodes B′=B∪ΔB is updated and the set of edges E′=E∪ΔE is updated, wherein ΔE={(f_{ug}, b_{ugh})|b_{ugh}∈ΔB}; and the obtained corresponding behavioral nodes and edges between the behavioral nodes and the functional nodes obtained in step S2 are added to the structural node graph network to obtain the first graph network.

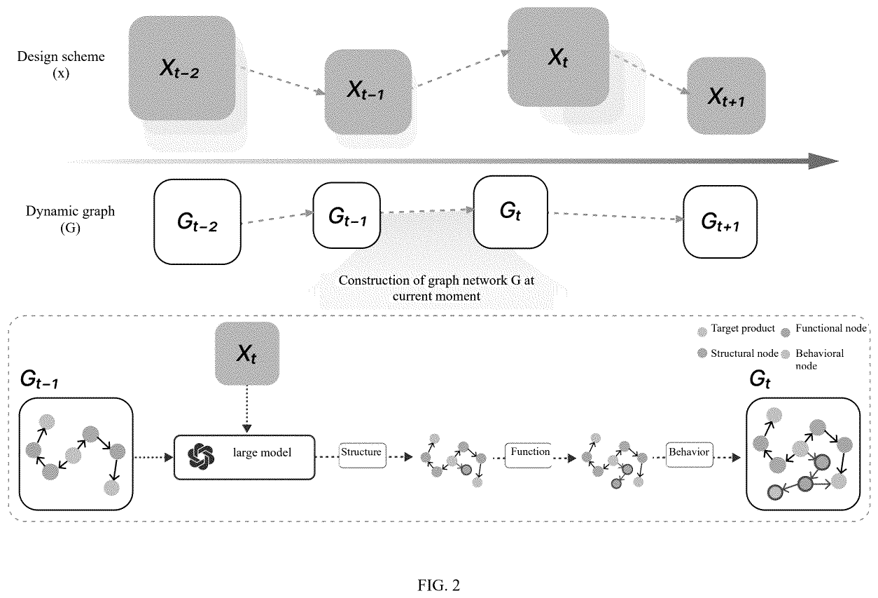

The specific embodiments of the present invention use the large language model to find a new structure, function, behavior, and their edges from the design scheme at the current moment based on the graph network at the previous moment, thereby constructing the graph network at the current moment corresponding to the design scheme at the current moment. As shown in FIG. 2, in each graph network of the dynamic graphs provided by the specific embodiments of the present invention, the graph network Gₜ at the current moment is obtained by updating the graph network Gₜ₋₁ at the previous moment, comprising:
extracting new structural nodes and edges between the new structural nodes and other structural nodes from the current design scheme by using the large language model based on the graph network at the previous moment; and updating the graph network at the previous moment to obtain the first graph network based on the extracted new structural nodes and the edges between the new structural nodes and other structural nodes.

In a specific embodiment, specific steps of extracting new structural nodes and edges between the new structural nodes and other structural nodes from the current design scheme by using the large language model based on the graph network at the previous moment provided in the specific embodiments of the present invention comprises:
inputting a first prompt word into the large language model to obtain the new structural nodes, wherein the first prompt word is constructed by a first instructional statement, a first output example, the current design scheme, and the graph network at the previous moment; the large language model obtains a first instruction through the first instructional statement; the first instruction is to obtain the new structural nodes; and the large language model makes a statement structure of an output result thereof the same as that of the first output example through the first output example; and
inputting a second prompt word into the large language model to obtain the edges between the new structural nodes and the other structural nodes, wherein the second prompt word is constructed by a second instructional statement, a second output example, a set of structural nodes, the current design scheme, and the graph network at the previous moment; the large language model obtains a second instruction through the second instructional statement; the second instruction is to obtain the edges between the new structural nodes and the other structural nodes; the large language model makes the statement structure of the output result thereof the same as that of the second output example through the second output example; the set of structural nodes comprises the new structural nodes and the other structural nodes; the other structural nodes are structural nodes contained in the graph network at the previous moment; and in a specific embodiment, the set of structural nodes is stored in a form of an adjacency list.

In the specific embodiments of the present invention, new functional nodes and edges between the new functional nodes and the new structural nodes and/or the other structural nodes are extracted from the current design scheme by using the large language model based on the first graph network; and the first graph network is updated to obtain a second graph network based on the extracted new functional nodes and edges between the new functional nodes and the new structural nodes and/or the other structural nodes.

In a specific embodiment, specific steps of extracting new functional nodes and edges between the new functional nodes and the new structural nodes and/or other structural nodes from the current design scheme by using the large language model based on the first graph network comprises:
inputting a third prompt word into the large language model to obtain the new functional nodes, wherein the third prompt word is constructed by a third instructional statement, a third output example, the current design scheme, the graph network at the previous moment and a set of structural nodes; the large language model obtains a third instruction through the third instructional statement; the third instruction is to obtain the new structural nodes; and the large language model makes a statement structure of an output result thereof the same as that of the third output example through the third output example; the set of structural nodes comprises the new structural nodes and the other structural nodes; and the other structural nodes are structural nodes contained in the graph network at the previous moment; and in a specific embodiment, the set of structural nodes is stored in the form of adjacency list; and
inputting a fourth prompt word into the large language model to obtain the edges between the new functional nodes and the new structural nodes and/or the other structural nodes, wherein the fourth prompt word is constructed by a fourth instructional statement, a fourth output example, the set of structural nodes, the current design scheme, the graph network at the previous moment and the set of structural nodes; the large language model obtains a fourth instruction through the fourth instructional statement; the fourth instruction is to obtain the edges between the new functional nodes and the new structural nodes and/or the other structural nodes; and the large language model makes the statement structure of the output result thereof the same as that of the fourth output example through the fourth output example.

In the specific embodiments of the present invention, new behavioral nodes and edges between the new behavioral nodes and the new functional nodes and/or other functional nodes are extracted from the current design scheme by using the large language model based on the second graph network; and updating the second graph network to obtain the graph network at the current moment based on the extracted new behavioral nodes and edges between the new behavioral nodes and the new functional nodes and/or other functional nodes.

In the specific embodiments of the present invention, specific steps of extracting new behavioral nodes and edges between the new behavioral nodes and the new functional nodes and/or other functional nodes from the current design scheme by using the large language model based on the second graph network comprises:
inputting a fifth prompt word into the large language model to obtain the new behavioral nodes, wherein the fifth prompt word is constructed by a fifth instructional statement, a fifth output example, the current design scheme, the graph network at the previous moment, a set of structural nodes, and a set of functional nodes; the large language model obtains a fifth instruction through the fifth instructional statement; the fifth instruction is to obtain the new behavioral nodes; the large language model makes a statement structure of an output result thereof the same as that of the fifth output example through the fifth output example; the set of structural nodes comprises the new structural nodes and the other structural nodes; the other structural nodes are structural nodes contained in the graph network at the previous moment; the set of functional nodes comprises the new functional nodes and the other functional nodes; the other functional nodes are functional nodes contained in the graph network at the previous moment; and in a specific embodiment, the set of structural nodes and the set of functional nodes are both stored in the form of adjacency list; and
inputting a sixth prompt word into the large language model to obtain the edges between the new behavioral nodes and the new functional nodes and/or the other functional nodes, wherein the sixth prompt word is constructed by a sixth instructional statement, a sixth output example, the set of structural nodes, the current design scheme, the graph network at the previous moment, the set of structural nodes, and the set of functional nodes; the large language model obtains a sixth instruction through the sixth instructional statement; the sixth instruction is to obtain the edges between the new behavioral nodes and the new functional nodes and/or the other functional nodes; and the large language model makes the statement structure of the output result thereof the same as that of the sixth output example through the sixth output example.

In the specific embodiments of the present invention, graph network data of function-behavior-structure is stored in the form of the adjacency list. Specifically, two classes, namely a node class and a graph class of the graph network, are defined.

In the specific embodiments of the present invention, the node class Vertex is defined as each node in the graph. The node comprises id, type, value, and neighbors. The id is an integer variable representing a sequence number of the node. The type is a string variable representing the type of the node, which comprises three values: “f”, “b”, and “s”, corresponding to the function, behavior, and structure respectively. The value is a string variable representing a semantic of the node. The neighbors is a list variable that stores sequence numbers of all adjacent nodes pointed to by the node.

In the specific embodiments of the present invention, the defined graph class represents an overall architecture of the graph network, which comprises graph_list, time, addVertex, addEdge, and is_Vertex_in_Graph, wherein the graph_list is a list variable that stores instances of all nodes in the graph, the time is a string variable indicating time when the graph is established, add Vertex is a function used to add a new node to the graph_list, addEdge is a function that updates the edges by updating a neighbors list of a specific node in the graph_list, and is_Vertex_in_Graph is used to determine whether a certain node exists in the graph.

The specific embodiments of the present invention provide that when the graph needs to be updated, a Vertex instance is created for the new node, and the addVertex function is called to add it to the graph. The addition of an edge is achieved by calling the addEdge function. Before adding the edge, the “is_Vertex_in_Graph” function needs to be called to determine whether two nodes connected by the edge already exist in the graph. If they do not exist in the graph, the nodes need to be added first.

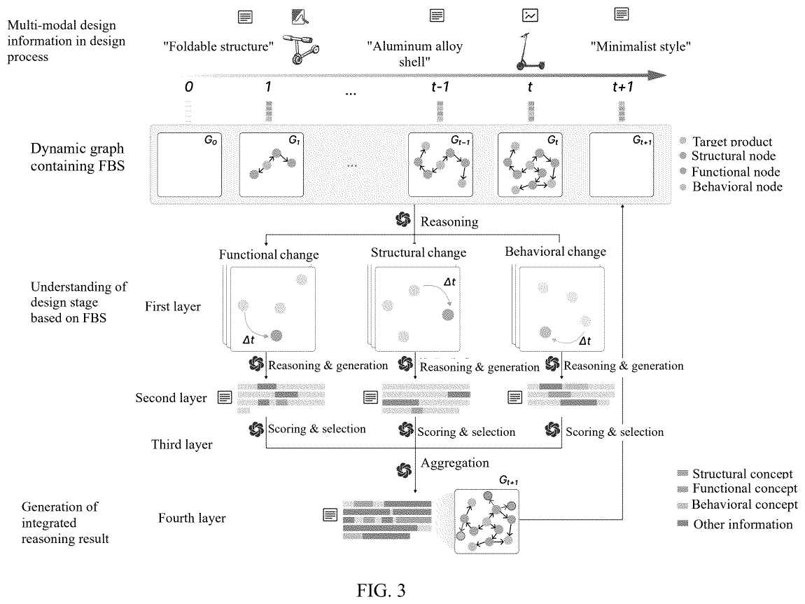

(2) as shown in FIG. 3, utilizing a mind map to perceive a design process and perform reasoning for the current design scheme based on structures of the graph networks at different moments: the mind map is utilized to compare the structures of the graph networks at different moments through the large language model to obtain change descriptions in three dimensions: the function, structure, and behavior, as shown in a first layer of FIG. 3, that is, connection relationships between the nodes (structural node, functional node, or behavioral node, represented by dark-colored dots in FIG. 3) at the current moment and the nodes (structural node, functional node, or behavioral node, represented by light-colored dots in FIG. 3) at the previous moment under time of Δt are used to obtain the corresponding change descriptions in the three dimensions through the large language model; the large language model is used to obtain a plurality of design schemes corresponding to each dimension respectively based on the change descriptions in the three dimensions of function, structure, and behavior; the large language model is used to evaluate the plurality of design schemes in each dimension respectively based on a set evaluation rule to obtain optimal design schemes corresponding to the function, structure, and behavior; and the optimal design schemes corresponding to the function, structure, and behavior are aggregated to obtain an optimized design scheme at the current moment.

In the specific embodiments of the present invention, a prompt word tuning method based on the mind map is adopted. The graph network containing “function-behavior-structure” is decomposed into the three dimensions: function, behavior, and structure. This guides the LLM to understand a design idea of the designer and a current design process in different dimensions by comparing the differences between the graphs at different moments. On this basis, a plurality of creative stimuli, that is, a plurality of design schemes, are generated for different dimensional situations respectively. The LLM or the designer scores and compares these schemes to select the optimal scheme for each dimension. Through the aggregation and optimization of these schemes, a reasoning result with complete logic and high relevance to the current design process is obtained.

The mind map provided in the specific embodiment of the present invention is a prompt tuning method. By modeling the reasoning process of the large language model (LLM) with a graph structure, it realizes the decomposition of tasks and the divergence and aggregation of thinking, thereby enhancing the LLM's reasoning ability for complex logics. A basic framework of the mind map comprises a controller, a prompt generator, a parser, and an evaluation model.

As shown in FIG. 3, the controller provided in the specific embodiments of the present invention comprises a reasoning state graph and an operation graph. The reasoning state graph consists of a plurality of thought nodes and edges among the thought nodes. The thought nodes comprise four levels: the thought nodes at a first level are the change descriptions in the three dimensions of function, structure, and behavior, and the thought nodes at this level are determined by comparing the graph networks at different moments obtained in step (1). The thought nodes at a second level are a plurality of design schemes corresponding to each dimension, which are obtained through reasoning and generating operation instructions based on the change description of each dimension, design schemes corresponding to the structure dimension contain structural concepts, those corresponding to the function dimension contain functional concepts, and those corresponding to the behavior dimension contain behavioral concepts. The thought nodes at a third level are the optimal design schemes selected from the plurality of design schemes of each dimension through scoring and selection operation instructions; and the thought nodes at a fourth level are the optimized design schemes at the current moment, which are obtained by performing aggregation operation instructions on the optimal design schemes of each dimension.

In the specific embodiments of the present invention, the edges among the thought nodes are used to represent the connection relationships among the thought nodes at different levels.

The operation graph provided in the specific embodiments of the present invention is an operation process constructed based on a plurality of operation instructions from the thought nodes at the first level to those at the fourth level, which are obtained from the reasoning state graph.

In the specific embodiments of the present invention, the prompt word generator is configured to generate corresponding prompt words based on each operation instruction, and input the prompt words into the large language model to generate descriptive information.

In a specific embodiment, the prompt generator provided in the specific embodiments of the present invention selects a pre-set prompt word framework for the corresponding operation according to an operation (generation, aggregation, or refinement) to be performed in current thought state node process control information and a current reasoning stage, embeds a variable containing specific input information, and generates a corresponding prompt word as an input for the LLM to guide the LLM to generate a corresponding feedback.

The parser provided in the specific embodiments of the present invention is used to extract key information from the descriptive information and structure the key information into the targeted thought nodes. The key information is content information that can be used to obtain the targeted thought nodes.

It is understandable that in the scoring stage provided in the specific embodiments of the present invention, the LLM returns a score and a reason for the score; in a next stage, when selecting a scheme with a highest score, only score information is needed, not the reason; and the parser extracts the score from the content returned by the LLM as a thought node.

The evaluation module provided in the specific embodiments of the present invention is configured to evaluate the plurality of design schemes in each dimension respectively through the large language model based on the set evaluation rule to obtain the optimal schemes corresponding to the three dimensions of function, structure, and behavior.

In a specific embodiment, the evaluation module provided in the specific embodiments of the present invention scores the design schemes under each dimension represented by the nodes in the reasoning state graph or verifies their correctness. The evaluation may be completed by the LLM, the designer, or by comprehensively considering evaluation results of both to enhance the rationality of the evaluation.

In the specific embodiments of the present invention, in order to make the scoring of the LLM for the schemes generated in an intermediate reasoning process more reasonable and interpretable, and to ensure consistency of evaluation criteria for different schemes, the present invention provides the following evaluation dimensions for product concept design schemes to the LLM: 1. Timeliness: whether the scheme content is highly relevant to the current design process. 2. Innovation: whether the product design provides a new solution or adopts an innovative technology, and whether it is significantly different from existing products. 3. User requirement satisfaction: whether the design scheme solves an actual problem of a user and meets requirements of the user. 4. Functionality: whether a function of the product is complete, whether it can effectively perform its intended function, and whether the function corresponds to the requirements of the user. 5. Usability: whether the product is easy to use and what the user experience is during a use process, comprising friendliness of an interface and intuitiveness of operations. 6. Technical feasibility: whether the technology on which the design scheme relies is mature and whether it can be actually manufactured or implemented. 7. Cost-effectiveness: evaluating the product design from a perspective of cost, comprising a production cost, a maintenance cost, etc. 8. Aesthetic design: whether the appearance, color, shape, etc. of the product are attractive to a target user group and whether they conform to an aesthetic trend.

In a specific embodiment, the reasoning of the design scheme by using the LLM in the specific embodiments of the present invention is carried out on the extracted graph network containing “function-behavior-structure”. In this embodiment, the graph network stored in a structured way is converted into a natural language and input into the LLM. The specific steps for pre-processing the graph network data stored in the structured way into a natural language description are as follows:

Each time the construction of the “function-behavior-structure” graph is completed, four strings are initialized: str_s=“structure”, str_f=“function”, str_b=“behavior”, and str_e=“relationship”.

Then, each node element “node” in the graph_list of the graph network instance is traversed, and its semantic value and serial number are connected in a form of string after the corresponding class according to the type of the node, that is, str_{node.type}+=“{node.value}({node.id})”. Elements in the member variable “neighbors” of the node “node” represent serial numbers of the adjacent nodes pointed to by this node, denoted as num. The elements in “node.neighbors” are traversed, and a pair (node.id, num) is connected in a form of string after “relationship”, that is, str_e+=“({node.id}, {num})”. Finally, connect the four strings, and then a natural-language description Dₜ=str_f+str_b+str_s+str_e of a “function-behavior-structure” graph Gₜ is obtained.

In the specific embodiments of the present invention, the natural-language descriptions {Dₜ₋ₖ₊₁, . . . , Dₜ} of the most recent k graphs are selected as thought contents of the initial nodes in the reasoning state graph of the mind-map framework, and the reasoning starts according to the process of the operation graph.

In the specific embodiments of the present invention, the operation instructions are used to make thought nodes at one level point to the thought nodes at a next level, and the operation instructions comprise generation, aggregation, refinement, scoring, and selection. The generation provided in this embodiment is a reasoning process of generating a plurality of thoughts from one thought. The LLM is used to decompose a large task into a plurality of sub-tasks or generate a plurality of solutions for a problem. The generation operation is manifested on the reasoning state graph as splitting of one thought node v into a plurality of new thought nodes, wherein M is the number of new thought nodes, and the set of new thought nodes and the edges between the new nodes and other nodes are:

$${Δ V}^{T} = \{ v {}_{1}^{+} , … , v {}_{M}^{+} \} , {Δ E}^{T} = \{ ( v , v {}_{1}^{+} ) , … , ( v , v {}_{M}^{+} ) \} .$$

The aggregation provided in this embodiment is a reasoning process of integrating a plurality of thoughts into one thought. The LLM is used to integrate and strengthen the advantages of the plurality of thoughts while eliminating conflicts among different thoughts. The aggregation operation is manifested on the reasoning state graph as a plurality of nodes pointing to one new thought node v⁺. The set of new thought nodes and the edges between the new nodes and other nodes are: ΔV^{T}={v⁺}, ΔE^{T}={(v₁, v⁺), . . . , (v_{M}, v⁺)}.

The refinement provided in this embodiment is a process of using the LLM to re-reason about the current thought and modify its content. The refinement operation is manifested on the reasoning state graph as the addition of a loop from a thought node v to itself, that is, ΔV^{T}=∅, ΔE^{T}={(v, v)}.

The scoring provided in this embodiment is to evaluate and assign scores to the thought nodes in the reasoning state graph. The LLM may be allowed to score according to relevant indicators, or the designer may conduct the scoring.

The selection provided in this embodiment is to rank specified thought nodes according to their scores and retain the top h nodes with the highest scores.

In the specific embodiments of the present invention, in order to enable the LLM to deeply understand the design idea of the designer and generate a reasoning result with complete logic and high relevance to the current design process, the present invention formulates the following operation process:

In the specific embodiments of the present invention, based on the natural-language descriptions input={Dₜ₋ₖ₊₁, . . . , Dₜ} of the “function-behavior-structure” graph networks at the most recent k moments, descriptions L={L_{f}, L_{b}, Lₛ}=φ_{generate0}(p_{θ}(Y|prompt_{generate0})) of the changes in the design scheme in terms of function, behavior, and structure during this stage are generated. The prompt word needs to guide the LLM to analyze the changes that have occurred in the dynamic graph of the current stage in terms of structure, function, and behavior respectively, as well as design issues that the designer may focus on in terms of structure, function, and behavior respectively. It should also contain the natural-language descriptions of the “function-behavior-structure” graphs at the most recent k moments and output examples. That is, prompt_{generate0}=<instruction_{generate0}, input, example>.

Based on the changes in the above three aspects, the design scheme is reasoned, and three possible schemes {Q_{z1}, Q_{z2}, Q_{z3}}=φ_{generate1}(p_{θ}(Y|prompt_{generate1})), zϵ{f, b, s} are generated for a dimension z. The prompt word needs to guide the LLM to provide a further deduction direction for the design scheme or a solution to existing problems based on the analysis of the previous reasoning stage. It should contain the descriptions of the changes in the design scheme in terms of function, behavior, and structure and output examples. That is, prompt_{generate1}=<instruction_{generate1}, L_{z}, example>, zϵ{f, b, s}.

The three schemes for each dimension are scored. The LLM gives scores Score1=φ_{score}(p_{θ}(Y|prompt_{score})) according to the given indicators. The prompt word needs to inform the LLM of a scoring criterion (such as usability, feasibility) and a scoring range, and contain the schemes generated for the function, behavior, and structure respectively, as well as the output That examples. is, prompt_{score}=<instruction_{score}, q, example>, qϵ{Q_{z1}, Q_{z2}, Q_{z3}}, zϵ{f, b, s}. The designer gives a subjective score of Score2. Then a final score of the scheme is Score=α·Score1+β·Score2, wherein α and β represent weights of the score of the LLM and the score of the designer respectively.

In the specific embodiments of the present invention, a scheme with a highest score in each dimension is retained

$${Q}_{z} = {max}_{Score} ( {Q}_{z 1} , {Q}_{z 2} , {Q}_{z 3} ) .$$

By integrating the optimal design schemes generated for the changes in the function, behavior, and structure respectively, a final reasoning result, that is, the optimized scheme at the current moment, is obtained R=φ_{aggregate}(p_{θ}(Y|prompt_{aggregate})). The prompt word needs to guide the LLM to integrate the three product concept design schemes, eliminate conflicting and redundant parts, and generate the final reasoning result. The prompt word prompt_{aggregate} input to the LLM contains the schemes generated for the function, behavior, and structure respectively, as well as the output examples. That is, prompt_{aggregate}=<instruction_{aggregate}, Q, example>, Q={Q_{f}, Q_{b}, Qₛ}.

In the specific embodiments of the present invention, after obtaining the optimized scheme at the current moment, step (1) is utilized to convert this optimized scheme into a corresponding graph network Gₜ₊₁. and this graph network Gₜ₊₁ is used for the construction of the graph network in the next stage and the reasoning of the design scheme.

What is claimed is:

1. A multi-modal design information unified expression and reasoning method based on a large language model, comprising the following steps:
extracting new structural nodes and edges between the new structural nodes and other structural nodes from a current design scheme by using the large language model based on a graph network at a previous moment, and updating the graph network at the previous moment to obtain a first graph network; extracting new functional nodes and edges between the new functional nodes and the new structural nodes and/or other structural nodes from the current design scheme by using the large language model based on the first graph network, and updating the first graph network to obtain a second graph network; and extracting new behavioral nodes and edges between the new behavioral nodes and the new functional nodes and/or other functional nodes from the current design scheme by using the large language model based on the second graph network, and updating the second graph network to obtain a graph network at a current moment; and
comparing graph networks at different moments through the large language model by using a mind map to obtain change descriptions in three dimensions of function, structure, and behavior; using the large language model to obtain a plurality of design schemes corresponding to each dimension respectively based on the change descriptions in the three dimensions of function, structure, and behavior; using the large language model to evaluate the plurality of design schemes in each dimension respectively based on a set evaluation rule to obtain optimal design schemes corresponding to the function, structure, and behavior; and aggregating the optimal design schemes corresponding to the function, structure, and behavior to obtain an optimized design scheme at the current moment.

2. The multi-modal design information unified expression and reasoning method based on a large language model according to claim 1, wherein the extracting new structural nodes and edges between the new structural nodes and other structural nodes from a current design scheme by using the large language model based on a graph network at a previous moment comprises:
inputting a first prompt word into the large language model to obtain the new structural nodes, wherein the first prompt word is constructed by a first instructional statement, a first output example, the current design scheme, and the graph network at the previous moment; the large language model obtains a first instruction through the first instructional statement; the first instruction is to obtain the new structural nodes; and the large language model makes a statement structure of an output result thereof the same as that of the first output example through the first output example; and
inputting a second prompt word into the large language model to obtain the edges between the new structural nodes and the other structural nodes, wherein the second prompt word is constructed by a second instructional statement, a second output example, a set of structural nodes, the current design scheme, and the graph network at the previous moment; the large language model obtains a second instruction through the second instructional statement; the second instruction is to obtain the edges between the new structural nodes and the other structural nodes; the large language model makes the statement structure of the output result thereof the same as that of the second output example through the second output example; the set of structural nodes comprises the new structural nodes and the other structural nodes; and the other structural nodes are structural nodes contained in the graph network at the previous moment.

3. The multi-modal design information unified expression and reasoning method based on a large language model according to claim 1, wherein the extracting new functional nodes and edges between the new functional nodes and the new structural nodes and/or other structural nodes from the current design scheme by using the large language model based on the first graph network comprises:
inputting a third prompt word into the large language model to obtain the new functional nodes, wherein the third prompt word is constructed by a third instructional statement, a third output example, the current design scheme, the graph network at the previous moment and a set of structural nodes; the large language model obtains a third instruction through the third instructional statement; the third instruction is to obtain the new structural nodes; and the large language model makes a statement structure of an output result thereof the same as that of the third output example through the third output example; the set of structural nodes comprises the new structural nodes and the other structural nodes; and the other structural nodes are structural nodes contained in the graph network at the previous moment; and
inputting a fourth prompt word into the large language model to obtain the edges between the new functional nodes and the new structural nodes and/or the other structural nodes, wherein the fourth prompt word is constructed by a fourth instructional statement, a fourth output example, the current design scheme, the graph network at the previous moment and the set of structural nodes; the large language model obtains a fourth instruction through the fourth instructional statement; the fourth instruction is to obtain the edges between the new functional nodes and the new structural nodes and/or the other structural nodes; and the large language model makes the statement structure of the output result thereof the same as that of the fourth output example through the fourth output example.

4. The multi-modal design information unified expression and reasoning method based on a large language model according to claim 1, wherein the extracting new behavioral nodes and edges between the new behavioral nodes and the new functional nodes and/or other functional nodes from the current design scheme by using the large language model based on the second graph network comprises:
inputting a fifth prompt word into the large language model to obtain the new behavioral nodes, wherein the fifth prompt word is constructed by a fifth instructional statement, a fifth output example, the current design scheme, the graph network at the previous moment, a set of structural nodes, and a set of functional nodes; the large language model obtains a fifth instruction through the fifth instructional statement; the fifth instruction is to obtain the new behavioral nodes; the large language model makes a statement structure of an output result thereof the same as that of the fifth output example through the fifth output example; the set of structural nodes comprises the new structural nodes and the other structural nodes; the other structural nodes are structural nodes contained in the graph network at the previous moment; the set of functional nodes comprises the new functional nodes and the other functional nodes; the other functional nodes are functional nodes contained in the graph network at the previous moment; and
inputting a sixth prompt word into the large language model to obtain the edges between the new behavioral nodes and the new functional nodes and/or the other functional nodes, wherein the sixth prompt word is constructed by a sixth instructional statement, a sixth output example, the current design scheme, the graph network at the previous moment, the set of structural nodes, and the set of functional nodes; the large language model obtains a sixth instruction through the sixth instructional statement; the sixth instruction is to obtain the edges between the new behavioral nodes and the new functional nodes and/or the other functional nodes; and the large language model makes the statement structure of the output result thereof the same as that of the sixth output example through the sixth output example.

5. The multi-modal design information unified expression and reasoning method based on a large language model according to claim 1, wherein the method for constructing the first graph network comprises:
S1: using the large language model to extract a target product from an initial design scheme, and taking the target product as a first structural node;
S2: using the large language model to extract structural nodes related to the first structural node and edges between the first structural node and related structural nodes thereof from the current design scheme based on the extracted first structural node, so as to obtain a structural node graph network;
S3: using the large language model to extract corresponding functional nodes and edges between the functional nodes and the structural nodes of the structural node graph network from the current design scheme based on the structural node graph network, and updating the structural node graph network based on the corresponding functional nodes and the edges between the functional nodes and the structural nodes of the structural node graph network to obtain a graph network containing the structural nodes and the functional nodes; and
S4: using the large language model to extract corresponding behavioral nodes and edges between the behavioral nodes and the functional nodes obtained in step S2 from the current design scheme based on the graph network containing the structural nodes and the functional nodes, and updating the graph network based on the corresponding behavioral nodes and the edges between the behavioral nodes and the functional nodes obtained in step S2 to obtain the first graph network.

6. The multi-modal design information unified expression and reasoning method based on a large language model according to claim 1, wherein the comparing graph networks at the previous moment and the current moment through the large language model by using a mind map to obtain change descriptions in three dimensions of function, structure, and behavior comprises:
decomposing the graph networks at the previous moment and the current moment into the three dimensions of function, behavior, and structure respectively through the mind map, and using the large language model to compare differences of each dimension at different moments so as to obtain the change descriptions in the three dimensions of function, structure, and behavior.

7. The multi-modal design information unified expression and reasoning method based on a large language model according to claim 1, wherein the mind map comprises a controller, a prompt word generator, a parser, and an evaluation module,
wherein the controller is configured to construct a reasoning state graph and an operation graph based on graph network data at different moments, wherein the reasoning state graph comprises a plurality of thought nodes and edges among the thought nodes, the thought nodes comprise four-level thought nodes, thought nodes of a first level are the change descriptions in the three dimensions of function, structure, and behavior, thought nodes of a second level are a plurality of design schemes corresponding to each dimension, thought nodes of a third level are optimal design schemes corresponding to each dimension, thought nodes of a fourth level are an optimized design scheme at the current moment, the edges among the thought nodes are used to represent connection relationships among the thought nodes at different levels, and the operation graph is an operation process constructed by a plurality of operation instructions from the thought nodes of the first level to the thought nodes of the fourth level based on the reasoning state graph;
the prompt word generator is configured to generate corresponding prompt words based on each operation instruction, and input the prompt words into the large language model to generate descriptive information;
the parser is configured to extract key information from the descriptive information and structure the key information into targeted thought nodes; and
the evaluation module is configured to evaluate the plurality of design schemes in each dimension respectively through the large language model based on the set evaluation rule to obtain the optimal schemes corresponding to the three dimensions of function, structure, and behavior.

8. The multi-modal design information unified expression and reasoning method based on a large language model according to claim 7, wherein the operation instructions are used to make thought nodes at a current level point to the thought nodes at a next level, and the operation instructions comprise generation, aggregation, refinement, scoring, and selection.

9. The multi-modal design information unified expression and reasoning method based on a large language model according to claim 1, wherein before inputting the graph network into the large language model, the graph network is stored in a form of an adjacency list, and the stored graph network is converted into a natural language description in a form of a string.
